(19) United States
(12) Patent Application Publication
(10) Pub. No.: US 2014/0267478 A1
(43) Pub. Date: Sep. 18, 2014

(54) LIQUID EJECTING HEAD, LIQUID EJECTING APPARATUS AND ACTUATOR APPARATUS

(71) Applicant: SEIKO EPSON CORPORATION, Tokyo (JP)

(72) Inventor: Naoto YOKOYAMA, Suwa-shi (JP)

(73) Assignee: SEIKO EPSON CORPORATION, Tokyo (JP)

(21) Appl. No.: 14/205,000

(22) Filed: Mar. 11, 2014

(30) Foreign Application Priority Data
Mar. 12, 2013 (JP) 2013-048838

(51) Int. Cl. B41J 2/14; H01L 41/09; B41J 2/07

(52) U.S. Cl. CPC B41J 2/14201; B41J 2/07; H01L 41/09
USPC 347/9; 347/70; 310/328

(57) ABSTRACT

A liquid ejecting head includes a flow path formation substrate provided with a pressure generation chamber communicated with at least one nozzle opening through which liquid is ejected; and an actuator apparatus including a vibration plate provided at one face side of the flow path formation substrate and a plurality of piezoelectric elements being formed on the vibration plate. The actuator apparatus includes two first piezoelectric elements arranged at positions facing edge portions in at least one direction of the pressure generation chamber and a second piezoelectric element arranged between the two first piezoelectric elements.

### BACKGROUND

1. Technical Field

The present invention relates to a liquid ejecting head, a liquid ejecting apparatus and an actuator apparatus each ejecting liquid through nozzle openings thereof, and in particular, relates to an ink jet recording head and an ink jet recording apparatus each ejecting ink as the liquid.

2. Related Art

In various types of piezoelectric elements, there exists a type of piezoelectric element which is for use in a liquid ejecting head or the like and which is configured such that a piezoelectric substance layer made of a piezoelectric material having an electromechanical conversion function, such as a crystallized dielectric material, is interposed between two electrodes. In addition, as a typical example of the liquid ejecting head, there exists, for example, an ink jet recording head which is configured such that, part of a pressure generation chamber communicated with a nozzle opening through which ink droplets are ejected is formed of a vibration plate, and an ink droplet is caused to be ejected through the nozzle opening by causing piezoelectric elements to deform the vibration plate to pressurize ink contained in the pressure generation chamber (refer to Japanese Patent No. 3387380 and JP-A-11-129468).

Nevertheless, there is a problem that, in a piezoelectric element having been subjected to repeated driving operations, a crystal structure of a piezoelectric substance layer thereof has been changed and an amount of displacement of the piezoelectric element becomes smaller than an amount of displacement thereof at the beginning of the repeated driving operations.

Further, such a problem similarly exists in a liquid ejecting head which ejects liquid other than the ink. Moreover, this problem is not a problem limited to an actuator apparatus mounted in the liquid ejecting head but a problem which similarly exists in an actuator apparatus for use in a different kind of device.

### SUMMARY

An advantage of some aspects of the invention is to provide a liquid ejecting head, a liquid ejecting apparatus and an actuator apparatus that have high reliability by suppressing the influence of increase of a residual distortion of piezoelectric elements included therein and thereby suppressing reduction of a displacement amount thereof over a long period of time.

According to a first aspect of the invention, a liquid ejecting head includes a flow path formation substrate provided with a pressure generation chamber communicated at least one nozzle opening through which liquid is ejected; and an actuator apparatus including a vibration plate provided at one face side of the flow path formation substrate and a plurality of piezoelectric elements being formed on the vibration plate, in which the actuator apparatus includes two first piezoelectric elements arranged at positions facing edge portions in at least one direction of the pressure generation chamber and a second piezoelectric element arranged between the two first piezoelectric elements.

According to this first aspect, the first piezoelectric elements and the second piezoelectric element compensate for each other's increase of a residual distortion, and thus, the influence of the increase of a residual distortion due to repeated driving operations is suppressed, and it becomes possible to suppress reduction of a displacement amount thereof.

Here, in the first aspect, preferably, the at least one direction corresponds to a direction in which the nozzle openings are aligned. According to this configuration, it becomes possible to effectively deform the vibration plate by using the two first piezoelectric elements and the second piezoelectric element.

Further, in the first aspect, the first piezoelectric elements are arranged at areas facing edge portions in a direction orthogonal to the at least one direction of the pressure generation chamber.

According to a second aspect of the invention, a liquid ejecting apparatus includes the liquid ejecting head according to the first aspect of the invention.

According to this second aspect, the variation of the characteristic of liquid ejection is suppressed over a long period of time, and it becomes possible to realize a liquid ejecting apparatus with enhanced reliability.

In the second aspect, preferably, the liquid ejecting apparatus further includes a control apparatus that supplies the first piezoelectric elements with a first driving signal and the second piezoelectric element with a second driving signal different from the first driving signal. According to this configuration, the first piezoelectric elements and the second piezoelectric element are driven at mutually different time points, and it becomes possible to allow the first piezoelectric elements and the second piezoelectric element to perform driving operations most suitable for liquid ejection.

Moreover, according to a third aspect of the invention, an actuator apparatus includes a vibration plate that defines and forms a face of a space portion; and a plurality of piezoelectric elements being formed on the vibration plate and including, two first piezoelectric elements arranged at positions facing edge portions in at least one direction of the space portion, and a second piezoelectric element arranged between the two first piezoelectric elements.

According to this third aspect, the first piezoelectric elements and the second piezoelectric element compensate for each other's increase of a residual distortion, and thus, the influence of the increase of a residual distortion due to repeated driving operations is suppressed, and it becomes possible to suppress reduction of a displacement amount thereof.

### BRIEF DESCRIPTION OF THE DRAWINGS

The invention will be described with reference to the accompanying drawings, wherein like numbers reference like elements.

FIG. 1 is a perspective view of a disassembled recording head according to embodiment 1 of the invention.

FIG. 2A is a substantial part plan view a recording head according to embodiment 1 of the invention; and FIG. 2B is a cross-sectional view of the recording head illustrated in FIG. 2A.

FIG. 3 is a substantial part cross-sectional view of a recording head according to embodiment 1 of the invention.

FIG. 4 is a schematic perspective view of a recording apparatus according to embodiment 1 of the invention.

FIG. 5 is a block diagram illustrating a control configuration according to embodiment 1 of the invention.

FIGS. 6A and 6B are driving waveforms illustrating driving signals according to embodiment 1 of the invention.

FIGS. 7A and 7B are driving waveforms illustrating modified examples of driving signals according to embodiment 1 of the invention.

FIGS. 8A and 8B are driving waveforms illustrating modified examples of driving signals according to embodiment 1 of the invention.

FIG. 9A is a substantial part plan view of a recording head according to another embodiment of the invention; and FIG. 9B is a cross-sectional view of the recording head illustrated in FIG. 9A.

FIG. 10 is a substantial part plan view of a recording head according to a further embodiment of the invention.

### DESCRIPTION OF EXEMPLARY EMBODIMENTS

Hereinafter, the invention will be described in detail on the basis of embodiments.

### Embodiment 1

FIG. 1 is a disassembled perspective view of an ink jet recording head which is an example of a liquid ejecting head according to this embodiment 1 of the invention; FIG. 2A is a plan view of a piezoelectric element side of a flow path formation substrate; FIG. 2B is a cross-sectional view taken along the line IIB-IIB of FIG. 2A; and FIG. 3 is a cross-sectional view taken along the line III-III of FIG. 2B.

As shown in FIGS. 1, 2A, 2B and 3, a flow path formation substrate 10 included in an ink jet recording head I, which is an example of a liquid ejecting head according to this embodiment, is formed of, for example, a silicon single-crystal substrate. In this flow path formation substrate 10, pressure generation chambers 12 partitioned by a plurality of partitioning walls 11 are arranged in parallel along a direction in which a plurality of nozzle openings 21, through each of which ink of the same color is ejected, align. Hereinafter, this direction will be referred to as an arrangement direction of the pressure generation chambers 12, or a first direction X. Further, a direction orthogonal to this first direction X will be referred to as a second direction Y.

Further, at a longitudinal-direction edge side of each of the pressure generation chambers 12 included in the flow path formation substrate 10, that is, at an edge side thereof in the second Y direction orthogonal to the first direction X, an ink feeding path 13, the opening area of which is made small by narrowing the width of the pressure chamber 12 from both sides thereof (in the first direction X), and a communication path 14, which has a width (in the first direction X) substantially the same as that of the ink feeding path 13, are partitioned by two adjacent ones of the plurality of partitioning walls 11. At an outside of the communication path 14 (at a side opposite a pressure generation chamber 12 side of the communication path 14 in the second Y direction), there is formed a communication portion 15 constituting part of a manifold 100 which is an ink chamber (a liquid chamber) common to each of the pressure generation chambers 12. That is, in the flow path formation substrate 10, there are provided liquid flow paths constituted of the pressure generation chambers 12, the ink feeding paths 13, the communication paths 14 and the communication portion 15.

A nozzle plate 20, in which holes for the nozzle openings 21 each communicating with one of the pressure generation chambers 12 are made, is bonded to a face of the flow path formation substrate 10, that is, a face of the flow path formation substrate 10 on which the liquid flow paths constituted of the pressure generation chambers 12 and the like form their respective openings, by using an adhesive agent, a thermal welding film or the like. That is, in the nozzle plate 20, the nozzle openings 21 are provided so as to align in the first direction X.

At another face of the flow path formation substrate 10, a vibration plate 50 is formed. In this embodiment, as the vibration plate 50, there is provided an elastic film 51, which is made of oxide silicon and is provided at a flow path formation substrate 10 side of the vibration plate 50, and an insulator film 52 which is made of zirconium oxide and is provided on the elastic film 51. In addition, the liquid flow paths constituted of the pressure generation chambers 12 and the like are formed by performing an anisotropic etching of the flow path formation substrate 10 from a face side of the liquid flow paths (a face side thereof to which the nozzle plate 20 is bonded), and another face of the liquid flow paths constituted of the pressure generation chambers 12 is defined and formed by the elastic film 51.

Here, it is essential that the vibration plate 50 (an electrode formation side thereof in the case where the vibration plate 50 is formed of a laminated film) is an insulator, and is capable of enduring a temperature at which a piezoelectric substance layer 70 is formed (generally, the temperature being equal to or higher than 500 degrees C.), and further, it is necessary that, in the case where a silicon wafer is used as the flow path formation substrate 10 and an anisotropic etching using potassium hydroxide (KOH) is employed when forming the flow paths constituted of the pressure generation chambers 12 and the like, the vibration plate 50 (a silicon wafer side thereof in the case where the vibration plate 50 is formed of a laminated film) functions as an etching stop layer. Further, in the case where silicon dioxide is used in part of the vibration plate 50, if lead, bismuth and the like included in the piezoelectric substance layer 70 diffuse into the silicon dioxide, the silicon dioxide changes its nature, so that upper layers, that is, the electrode and the piezoelectric substance layer 70, exfoliate. Thus, a diffusion prevention layer for preventing the diffusion into the silicon dioxide becomes necessary.

The vibration plate 50 obtained by laminating the silicon dioxide and the zirconium oxide is most suitable, because their respective materials are capable of enduring a temperature at the time when forming the piezoelectric substance layer 70, and besides, the silicon dioxide functions as an insulating layer and the etching stop layer, as well as the zirconium oxide functions as an insulating layer and the diffusion prevention layer. Although, in this embodiment, the vibration plate 50 is formed of these elastic film 51 and insulator film 52, only any one of the elastic film 51 and insulator film 52 may be provided as the vibration plate 50. Moreover, a portion of the flow path formation substrate 10 can be used as the vibration plate 50 by performing a thinning process on the portion thereof.

Further, on the insulator film 52, there are formed piezoelectric elements 300 each including a first electrode 60, the piezoelectric substance layer 70 and a second electrode 80.

Specifically, the piezoelectric elements 300 include, for each of the pressure generation chambers 12, two first piezoelectric elements 301 arranged at positions each facing a corresponding one of edge portions of the pressure generation chamber 12 in the first direction X, and a second piezoelectric element 302 arranged between the two first electrode elements 301. That is, three piezoelectric elements are formed for one of the pressure generation chambers 12. In addition, hereinafter, the first piezoelectric element 301 and the second piezoelectric element 302 will be also collectively referred to as the piezoelectric element 300.

Here, the first piezoelectric element 301 is provided so as to be across an edge portion of the pressure generation chamber 12, that is, a boundary portion between the pressure generation chamber 12 and the partitioning wall 11 therefor.

Further, the second piezoelectric element 302 is provided so as to face the pressure generation chamber 12, that is, the second piezoelectric element 302 is not provided on the partition wall 11 but is provided on the central portion of the pressure generation chamber 12.

In addition, in this embodiment, an actuator apparatus is constituted by the vibration plate 50, and the piezoelectric elements 300 including, for each of the pressure generation chambers 12, the two first piezoelectric elements 301, and the second piezoelectric element 302 arranged between the two first piezoelectric elements 301.

Further, in general, with respect to each of the piezoelectric elements 300, any one of electrodes thereof is made a common electrode, and the other one of the electrodes thereof is made a discrete electrode by performing a patterning process for each of the pressure generation chambers 12, or for each of the second piezoelectric element 302 and the first piezoelectric elements 301. Further, here, in each of the piezoelectric elements 300, a portion, which is constituted of any one of the electrodes thereof, having been subjected to the patterning process, and the piezoelectric substance layer 70, and in which a pressure distortion is caused by applying a voltage between both of the electrodes thereof, is referred to as an active portion 320.

In this embodiment, a first electrode 60 and a second electrode 80 are made a common electrode and a discrete electrode, respectively, and there is no trouble even when this correspondence relation is reversed for the sake of a convenience of a driving circuit and wiring. Incidentally, in this embodiment, the first electrode 60 is made the common electrode by continuously forming the first electrode 60 across the plurality of first piezoelectric elements 301 and the plurality of second piezoelectric elements 302. Naturally, the configuration of the first electrode 60 is not limited to this, and the first electrode 60 may be composed of, for example, two electrodes, a first one being a common electrode which is dedicated to the first piezoelectric elements 301 and which is continuously formed across the plurality of first piezoelectric elements 301, a second one being a common electrode which is dedicated to the second piezoelectric elements 302 and which is continuously formed across the plurality of second piezoelectric elements 302. Further, in this embodiment, the second electrode 80 is independently provided for each of the first piezoelectric nodes 301 and the second piezoelectric nodes 302, but the configuration is not particularly limited to this and, for example, the second electrodes 80 of the two first piezoelectric elements provided for each of the nozzle openings 21 may be provided so as to be electrically continuous with each other.

The piezoelectric substance layer 70 for use in such piezoelectric element 300 is made of a piezoelectric material which is an oxide of a polarization structure and which is formed on the first electrode 60. Further, the piezoelectric substance layer 70 can be made of, for example, a perovskite oxide represented by a general formula ABO₃, the “A” including lead, the “B” including at least one of zirconium and titanium. The above “B” can further include, for example, niobium. Specifically, as the piezoelectric substance layer 70, for example, titanic acid zirconic acid lead (Pb(Zr,Ti)O₃:PZT), niobic acid titanic acid zirconic acid lead (Pb(Zr,Ti,Nb)O₃:PZTNS) or the like can be employed.

Further, the piezoelectric substance layer 70 may be made of a non-lead-based piezoelectric material which does not include lead, such as a composite oxide which has a perovskite structure and which includes bismuth ferrate or bismuth manganate ferrate as well as barium titanate or bismuth potassium titanate.

Moreover, a lead electrode 90, which is made of, for example, gold (Au) and the like and which is pulled out from a vicinity of an ink feeding path 13 side edge of each of the piezoelectric elements 300 and is extended onto the insulator film 52, is electrically connected to each of the second electrodes 80, which is a discrete electrode of each of the piezoelectric elements 300.

A protection substrate 30, which includes a manifold portion 31 constituting at least part of the manifold 100, is bonded, via an adhesive agent 35, onto the flow path formation substrate 10 in which the piezoelectric elements 300 are formed, that is, onto the vibration plate 50, the first electrode 60 and the lead electrodes 90. In this embodiment, this manifold portion 31 is formed so as to penetrate the protection substrate 30 in its thickness direction and spread in a direction across the widths of the generation chambers 12, and, as described above, the manifold portion 31 constitutes the manifold 100 which becomes an ink chamber common to the individual pressure generation chambers 12 by being communicated with the communication portion 15 of the flow path formation substrate 10. Further, only the manifold portion 31 may be made a manifold by dividing, for each of the pressure generation chambers 12, the communication portion 15 of the flow path formation substrate 10 into a plurality of portions. Moreover, the configuration may be made such that, for example, only the pressure generation chambers 12 are provided in the flow path formation substrate 10, and the ink feeding path 13 for allowing the above manifold to communicate with each of the pressure generation chambers 12 is provided in the elastic film 51 and the insulator film 52 which are interposed between the flow path formation substrate 10 and the protection substrate 30.

The protection substrate 30 is provided with a piezoelectric actuator retention portion 32 having a size of a degree that does not block the movement of each of the piezoelectric elements 300 in an area facing the piezoelectric elements 300. In addition, the configuration of the piezoelectric actuator retention portion 32 is sufficient provided that it has a space having a size of a degree that does not block the movements of the piezoelectric elements 300, and it does not matter whether or not the space is hermetically closed.

Further, the protection substrate 30 is provided with a penetration hole 33 penetrating the protection substrate 30 in its thickness direction. Further, the vicinity of an edge portion of each of the lead electrodes 90, which is pulled out from a corresponding one of the piezoelectric elements 300, is provided so as to be exposed within the penetration hole 33.

Further, a driving circuit 120 functioning as a signal processing portion is fixed on the protection substrate 30. As the driving circuit 120, for example, a circuit board, a semiconductor integrated circuit (IC) or the like can be used. Further, the driving circuit 120 is electrically connected to each of the lead electrodes 90 via a connection wiring 121 which is formed of a piece of conductive wire, such as a piece of bonding wire, and which is inserted into the penetration hole 33.

It is preferable to use, as the protection substrate 30, a material whose coefficient of thermal expansion is substantially the same as that of the flow path formation substrate 10, such as a glass material or a ceramic material, and in this embodiment, the protection substrate 30 is formed by using a silicon single-crystal substrate whose material is the same as that of the flow path formation substrate 10.

Further, a compliance substrate 40 formed of a sealing film 41 and a fixing plate 42 is bonded onto the protection substrate 30. Here, this sealing film 41 is formed of a material having low rigidity and flexibility, such as a polyphenylene sulfide (PPS) film, and a face of the manifold portion 31 is sealed by this sealing film 41. Further, the fixing plate 42 is formed of a hard material, such as a metallic material (for example, stainless steel (SUS) or the like). An area being a portion of this fixing plate 42 and being located at the opposite side of the sealing film 41 from the manifold 100 is an opening 43 resulting from completely removing the portion of the fixing plate 42 in its thickness direction, and thus, a face of the manifold 100 is sealed by only the sealing film 41 having flexibility.

In such ink jet recording head I according to this embodiment, after ink has been taken in from an ink feeding port (not illustrated) connected to an external ink feeding means and the inside of the ink jet recording head I from the manifold 100 up to the nozzle openings 21 has been filled with the ink, each of portions of the vibration plate 50 is caused to bend and become deformed by driving, in accordance with a recording signal from the driving circuit 120, the first piezoelectric elements 301 and the second piezoelectric element 302 which are associated with a corresponding one of the pressure generation chambers 12, so that the each of the deformed portions of the vibration plate 50 causes pressure inside the corresponding one of the pressure generation chambers 12 to increase, thereby causing an ink droplet to be ejected through the nozzle opening 21 associated with the corresponding one of the pressure generation chambers 12.

Here, the ink jet recording head I according to this embodiment constitutes part of a head unit provided with ink flow paths each communicated with a cartridge or the like, and is mounted in an ink jet recording apparatus. FIG. 4 is a schematic diagram illustrating an example of such an ink jet recording apparatus.

As shown in FIG. 4, in a head unit 1 including the ink jet recording heads I, cartridges 2 each constituting an ink feeding means are provided so as to be attachable and detachable, and a carriage 3 including this head unit 1 mounted thereon is provided through a carriage shaft 5, which is attached to an apparatus body 4, so as to be freely movable in a direction along the carriage shaft 5. This head unit 1 is configured to so as to eject, for example, a black ink composition and color ink compositions.

A driving force of a driving motor 6 is transmitted to the carriage 3 via a plurality of toothed-gears (not illustrated) and a timing belt 7, and thereby the carriage 3 including the head unit 1 mounted thereon is moved along the carriage shaft 5. Meanwhile, a platen 8 is provided in the apparatus body 4 along the carriage shaft 5, and a recording sheet S, which is a recording medium, such as paper, and which is paper-fed by a paper feeding roller (not illustrated), is transported in the state of being wound and hung on the platen 8.

Further, in an ink jet recording apparatus II, a control apparatus (a printer controller) 500 for controlling the ink jet recording heads I is mounted.

Here, a control configuration for controlling driving of the ink jet recording head I will be described with reference to FIG. 5. In addition, FIG. 5 is a block diagram illustrating a control configuration for controlling an ink jet recording head.

As shown in FIG. 5, the ink jet recording apparatus II is substantially constituted by the printer controller 500 and a print engine 600. The printer controller 500 includes an external interface 501 (hereinafter, referred to as an external I/F 501); a RAM 502 for temporarily storing various pieces of data therein; a ROM 503 for storing control programs and the like therein; a control unit 504 configured to include a CPU and the like; an oscillation circuit 505 for generating clock signals; a driving signal generation circuit 506 for generating driving signals supplied to the ink jet recording heads I; and an internal interface 507 (hereinafter, referred to as an internal I/F 507) for transmitting dot pattern data (bit map data) or the like, which is developed on the basis of the driving signals and print data, to the print engine 600.

The external I/F 501 receives print data composed of, for example, character codes, graphic functions, image data and the like from a host computer (not illustrated) or the like. Further, through this external I/F 501, a busy signal (BUSY) and an acknowledge signal (ACK) are outputted to the host computer or the like. The RAM 502 functions as a reception buffer 508, an intermediate buffer 509, an output buffer 510 and a work memory (not illustrated). Further, the reception buffer 508 temporarily stores therein print data received by the external I/F 501; the immediate buffer 509 stores therein data converted by the control unit 504; and the output buffer 510 stores dot pattern data therein. In addition, this dot pattern data is composed of printing data which is obtained by decoding (translating) gray-scale data.

Further, the ROM 503 is configured to store therein font data, graphic functions and the like, in addition to control programs for causing the control unit 504 to execute various data processes. The control unit 504 retrieves print data stored in the reception buffer 508, and further, stores intermediate code data obtained by converting the retrieved print data into the intermediate buffer 509. Further, the control unit 504 analyzes the intermediate code data having been retrieved from the intermediate buffer 509, and develops the intermediate code data into dot pattern data by referring the font data, the graphics functions and the like stored in the ROM 503. Further, the control unit 504 performs necessary decoration processing on the developed dot pattern data, and then, stores this resultant dot pattern data into the output buffer 510.

Further, when dot pattern data corresponding to one line of data to be processed by one of the ink jet recording heads I has been obtained, this one line of dot pattern data is outputted to the relevant ink jet recording head I though the internal I/F 507. Further, when the one line of dot pattern data has been outputted from the output buffer 510, the already developed intermediate code data is erased from the intermediate buffer 508, and development processing on next intermediate code data is performed.

Further, in this embodiment, the driving signal generation circuit 506 generates a first driving signal (COM 1) and a second driving signal (COM 2), and the details thereof will be described below.

The print engine 600 is configured so as to include the ink jet recording heads I, a paper feeding mechanism 601 and a carriage mechanism 602. The paper feeding mechanism 601 is configured so as to include a paper feeding motor, the platen 8 (refer to FIG. 4) and the like, and sequentially feeds the recording paper S, which is a recorded medium, in conjunction with recording operations of the ink jet recording heads I. That is, this paper feeding mechanism 601 causes the recording paper S to make a relative movement in a sub-scanning direction relative to the ink jet recording heads I.

The carriage mechanism 602 is configured so as to include the carriage 3 capable of mounting the ink jet recording heads I thereon and a carriage driving portion which causes the carriage 3 to travel in a main-scanning direction, and the carriage mechanism 602 causes the ink jet recording heads I to move in the main-scanning direction by causing the carriage 3 to travel. In addition, the carriage driving portion is constituted of the driving motor 6, the timing belt 7 and the like which have been described above (refer to FIG. 4).

Each of the ink jet recording heads I includes a large number of the nozzle openings 21 along the sub-scanning direction, and ejects liquid droplets through each of the nozzle openings 21 at timing points defined by the dot pattern data or the like. Further, in the ink jet recording head I, the piezoelectric elements 300 provided for each of the nozzle openings 21 are supplied with electric signals, such as driving signals (COM 1 and COM 2) and printing data (SI), which will be described below. In addition, in the printer controller 500 and the print engine 600 which are configured in such a way as described above, the printer controller 500 and the driving circuit 120 which selectively inputs driving signals being outputted from the driving signal generation circuit 506 and having predetermined driving waveforms to a set of the piezoelectric elements 300 and which includes a shift register 122, a latch 123, a level shifter 124, a switch 125 and the like become a driving means for applying predetermined driving signals to a set of the piezoelectric elements 300.

In addition, the shift register 122, the latch 123, the level shifter 124, the switch 125 and the set of the piezoelectric elements 300 which have been described above are provided for each of the nozzle openings 21 included in the ink jet recording head I, and these shift register 122, latch 123, level shifter 124 and switch 125 generate driving pulses from ejection driving signals and release driving signals which are generated by the driving signal generation circuit 506. Here, the driving signals mean application pulses which are actually applied to the piezoelectric elements 300 provided for each of the nozzle openings 21.

In the ink jet recording head I, first, a string of the printing data (SI) composed of dot pattern data is serially transmitted from the output buffer 510 to the shift registers 122 in synchronization with a clock signal (CK) supplied from the oscillation circuit 505 and is sequentially set into the individual shift registers 122. In this case, first, a string of most significant bit data of the printing data for all the nozzle openings 21 is serially transmitted, and after the completion of this serial transmission of the string of most significant bit data, a string of second significant bit data is serially transmitted. Subsequently, in the same way, strings of less significant bit data are sequentially serially transmitted.

Further, when a string of relevant bit data of the printing data for all the nozzles has been completely set into each of the shift registers 122, the control unit 504 outputs the latch signal (LAT) to each of the latches 123 at predetermined timing. Upon receipt of this latch signal, each of the latches 123 latches the print data having been set in a corresponding one of the shift registers 122. The print data (LATout) having been latched by each of the latches 123 is applied to a corresponding one of the level shifters 124. In the case where a value of the print data is, for example, “1”, this level shifter 124 raises the voltage of the print data up to a voltage which makes it possible to drive a corresponding one of the switches 125, the voltage being, for example, several tens of voltages. Further, this print data whose voltage has been raised is applied to the switch 125, which transits into a connection state.

Further, driving signals (COM 1 and COM 2) generated by the driving signal generation circuit 506 are applied to each of the switches 125, and when a certain one of the switches 125 is selectively made in the connection state, the driving signals are selectively applied to a set of the piezoelectric elements 300 connected to the relevant switch 125. In this way, in the exemplified ink jet recording head I, it is possible to control whether or not ejection driving signals are to be applied to the piezoelectric elements 300 provided for each of the nozzle openings 21 in accordance with a corresponding piece of printing data. For example, during a period when a piece of print data is “1”, a corresponding one of the switches 125 is made in the connection state by the latch signal (LAT), and thus, driving signals (COMout) are supplied to the piezoelectric elements 300 provided for a corresponding one of the nozzle openings 21, so that the piezoelectric elements 300 provided for the corresponding one of the nozzle openings 21 are displaced (deformed) by the supplied driving signals (COMout). Further, during a period when a piece of print data is “0”, a corresponding one of the switches 125 is made in a non-connection state, and thus, the supply of the driving signals to the piezoelectric elements 300 provided for a corresponding one of the nozzle openings 21 is cut off. In addition, during a period when a piece of print data is “0”, the piezoelectric elements 300 provided for a corresponding one of the nozzle openings 21 each maintain an immediately prior electric potential, and thus, an immediately prior displacement state is maintained.

Here, a driving waveform representing a driving signal (COM) according to this embodiment, which is inputted to each of the piezoelectric elements 300, will be described. In addition, FIGS. 6A and 6B each illustrate a driving waveform representing a driving signal according to this embodiment.

In this embodiment, as the piezoelectric elements 300, the first piezoelectric elements 301 and the second piezoelectric elements 302 are provided, each of the first piezoelectric elements 301 being supplied with the first driving signal (COM 1), each of the second piezoelectric elements 302 being supplied with the second driving signal (COM 2).

The first driving signal COM 1 forms a pulse waveform shown in FIG. 6A and the second driving signal COM 2 forms a pulse waveform shown in FIG. 6B. Further, timing of applying the first driving signal COM 1 to the first piezoelectric element 301 is different from timing of applying the second driving signal COM 2 to the second piezoelectric element 302.

Specifically, the first driving signal COM 1 is a signal applied to the second electrode 80 which is a discrete electrode of each of the first piezoelectric elements 301, and as shown in FIG. 6A, the first driving signal COM 1 includes an ejection pulse generated for each recording cycle T. This ejection pulse included in the first driving signal COM 1 is composed of a first expansion element P01 which expands the pressure generation chamber 12 by ascending from a baseline electric potential V0 up to an electric potential V1; a first holding element P02 which holds the first electric potential V1 for a predetermined period of time; and a first compression element P03 which compresses the pressure generation chamber 12 by descending from the first electric potential V1 up to the baseline electric potential V0.

That is, as shown in FIG. 3, the first piezoelectric element 301 is provided across the portioning wall 11 and the pressure generation chamber 12, and thus, upon application of a voltage to the first piezoelectric element 301, the vibration plate 50 is deformed so as to become convex in a direction opposite the nozzle plate 20.

Meanwhile, the second driving signal COM 2 is a signal applied to the second electrode 80 which is a discrete electrode of each of the second piezoelectric elements 302, and as shown in FIG. 6B, the second driving signal COM 2 includes an ejection pulse generated for each recording cycle T. This ejection pulse included in the second driving signal COM 2 is composed of a second compression element P11 which compresses the pressure generation chamber 12 by ascending from the baseline electric potential V0 up to the electric potential V1; a second holding element P12 which holds the first electric potential V1 for a predetermined period of time; and a second expansion element P13 which expands the pressure generation chamber 12 by descending from the first electric potential V1 up to the baseline electric potential V0.

That is, the second pressure element 302 is provided in an area facing the pressure generation chamber 12, and thus, upon application of a voltage to the second pressure element 302, the vibration plate 50 is deformed so as to become convex in a direction opposite the direction of the deformation of the first piezoelectric element 301, that is, in a direction towards the nozzle plate 20.

Further, when the first driving signal COM 1 and the second driving signal COM 2 which have been described above are applied to the first piezoelectric element 301 and the second piezoelectric element 302, respectively, the pressure generation chamber 12 is expanded by the first expansion element P01 of the first driving signal COM 1, and thereby a meniscus inside the nozzle opening 21 is pulled in in a direction towards the pressure generation chamber 12. Next, the pressure generation chamber 12 is compressed by the first compression element P03, and simultaneously therewith, the pressure generation chamber 12 is compressed by the second compression element P11 of the second driving signal COM 2. In conjunction with pressurization of ink inside the pressure generation chamber 12 by these first compression element P03 and second compression element P11, the meniscus inside the pressure generation chamber 12 is largely pushed out from the pressure generation chamber 12 side, and the ink is ejected as an ink droplet through the nozzle opening 21. Subsequently, the pressure generation chamber 12 is restored to a baseline volume by the expansion element P13 of the driving signal COM 2.

In this way, timing at which the second compression element P11 of the driving signal COM 2 is applied is configured so as to be the same as timing at which the first compression element P03 of the driving signal COM 1 is applied. That is, it is possible to drastically reduce the volume of the pressure generation chamber 12 and further make a reduction amount (an excluded volume) thereof large by causing the second piezoelectric element 302 to compress the volume of the pressure generation chamber 12 simultaneously with causing the two first piezoelectric elements interposing the relevant second piezoelectric element 302 therebetween to compress the volume of the pressure generation chamber 12. That is, as compared with a case where an ink droplet is ejected merely by using any one of the first piezoelectric element 301 and the second piezoelectric element 302, a reduction amount of the volume of the pressure generation chamber 12 (i.e., an excluded volume of the pressure generation chamber 12) and a reduction ratio per unit time can be made larger by ejecting an ink droplet in a way utilizing piezoelectric distortions of both the first piezoelectric element 301 and the second piezoelectric element 302, so that it is possible to enhance the characteristic of ejection of an ink droplet.

Further, in general, repeated driving operations on a piezoelectric element cause its crystal structure to change, so that its displacement amount is reduced. Such a displacement reduction of the piezoelectric element caused by the repeated driving operations is mainly due to an increase of a residual distortion (an increase of residual polarization and an increase of a residual bending amount). In addition, the residual distortion means a distortion (a displacement amount) caused by a phenomenon in which, when an electric field applied to a piezoelectric element (a piezoelectric substance layer) is released, the piezoelectric substance layer is not depolarized and a polarization state thereof remains.

In this embodiment, however, a direction of a residual distortion of the first piezoelectric element 301, that is, a direction of a deformation thereof due to the residual distortion thereof, is a direction in which the first piezoelectric element 301 becomes convex in a direction opposite the nozzle plate 20; while, in contrast, a direction of a residual distortion of the second piezoelectric element 302, that is, a direction of a displacement thereof due to the residual distortion thereof, is a direction in which the second piezoelectric element 302 becomes convex in a direction towards the nozzle plate 20. That is, in this embodiment, a direction of a deformation of the first piezoelectric element 301 due to a residual distortion thereof and a direction of a deformation of the second piezoelectric element 302 due to a residual distortion thereof are made reverse to each other. In this way, the first piezoelectric element 301 and the second piezoelectric element 302 have a relationship in which a deformation of each thereof due to a residual distortion of the each thereof compensates for a deformation of the other one thereof due to a residual distortion of the other one thereof. Thus, the first piezoelectric element 301 and the second piezoelectric element 302 compensate for each other's increase of a residual distortion, so that it becomes possible to suppress the influence of a displacement reduction of each of the piezoelectric elements 300 due to repeated driving operations thereon.

Incidentally, when only the first piezoelectric element 301 is provided, repeated driving operations causes a residual distortion thereof through which the vibration plate 50 becomes convex in a direction opposite the nozzle plate 20, and this residual distortion causes a displacement reduction of the first piezoelectric element 301. Similarly, when only the second piezoelectric element 302 is provided, repeated driving operations causes a residual distortion thereof through which the vibration plate 50 becomes convex in a direction towards the nozzle plate 20, and this residual distortion causes a displacement reduction of the second piezoelectric element 302.

In this embodiment, the first piezoelectric element 301 and the second piezoelectric element 302 compensate for each other's residual distortion, and thus, this compensation makes the increase of influence of the residual distortion of each of the first piezoelectric element 301 and the second piezoelectric element 302 hard, and thus, this compensation makes it possible to suppress the influence of a reduction of a displacement amount of each of the piezoelectric elements 300 due to repeated driving operations thereon.

Further, in this embodiment, a configuration is made such that, when a voltage is applied to the first piezoelectric element 301, no voltage is applied to the second piezoelectric element 302, and when a voltage is applied to the second piezoelectric element 302, no voltage is applied to the first piezoelectric element 301. This configuration makes a direction in which the first piezoelectric element 301 is deformed by being driven a direction in which the first piezoelectric element 301 becomes convex in a direction opposite the nozzle plate 20; while, in contrast, a direction of a residual distortion of the second piezoelectric element 302, that is, a direction in which the second piezoelectric element 302 is deformed by a residual distortion thereof, is a direction in which the second piezoelectric element 302 becomes convex in a direction towards the nozzle plate 20. That is, a direction in which the first piezoelectric element 301 is deformed by being driven and a direction in which the second piezoelectric element 302 is deformed by a residual distortion thereof are made reverse to each other. In this way, the first piezoelectric element 301 and the second piezoelectric element 302 have a relationship in which a deformation of each thereof caused by driving the each thereof compensate for a deformation of the other one thereof caused by a residual distortion of the other one thereof. Thus, the first piezoelectric element 301 and the second piezoelectric element 302 compensate for each other's increase of a residual distortion, so that it becomes possible to suppress the influence of a displacement reduction of each of the piezoelectric elements 300 due to repeated driving operations thereon.

As described above, through providing the first piezoelectric elements 301 and the second piezoelectric elements 302 and driving these two kinds of piezoelectric element such that ink droplets are ejected, it is possible to suppress the influence of increase of a residual distortion of each of the first piezoelectric element and the second piezoelectric element and suppress the influence of a displacement reduction of each of the piezoelectric elements 300 due to repeated driving operations thereon. Accordingly, the characteristic of ejection of ink droplets is unlikely to vary over a long period of time, so that it becomes possible to enhance the reliability of ejection of ink droplets.

In addition, in this embodiment, the pulse waveforms of the first driving signal (COM 1) and the second driving signal (COM 2) have been exemplified, but the pulse waveforms thereof are not particularly limited to these ones. Here, a modified example of the driving signals will be described with reference to FIGS. 7A and 7B.

The first driving signal COM 1 is a signal to be applied to the second electrode 80 which is a discrete electrode of each of the first piezoelectric elements 301, and as shown in FIG. 7A, the first driving signal COM 1 includes an ejection pulse generated for each recording cycle T. This ejection pulse included in the first driving signal COM 1 is composed of a first expansion element P21 which expands the pressure generation chamber 12 by ascending from a state where an intermediate electric potential VM is maintained to the first electric potential V1; a first holding element P22 which holds the first electric potential V1 for a predetermined period of time; and a first compression element P23 which compresses the pressure generation chamber 12 by descending from the first electric potential V1 to a second electric potential V2; a second holding element P24 which holds the second electric potential V2 for a predetermined period of time; and a second expansion element P25 which expands the pressure generation chamber 12 by ascending from the second electric potential V2 to the intermediate electric potential VM. In addition, it is preferable that the second electric potential V2 of the first driving signal COM 1 corresponds to a coercive electric field of the first piezoelectric element 301.

Meanwhile, the second driving signal COM 2 is a signal to be applied to the second electrode 80 which is a discrete electrode of each of the second piezoelectric elements 302, and as shown in FIG. 7B, the second driving signal COM 2 includes an ejection pulse generated for each recording cycle T. This ejection pulse included in the second driving signal COM 2 is composed of an expansion element P31 which expands the pressure generation chamber 12 by ascending from a state where the second electric potential V2 is maintained to the first electric potential V1; a holding element P32 which holds the first electric potential V1; and an expansion element P33 which expands the pressure generation chamber 12 by descending from the first electric potential V1 to the second electric potential V2. In addition, it is preferable that the first electric potential V1 of the second driving signal COM 2 is the same electric potential as that of the first electric potential V1 of the above-described first driving signal COM 1. Further, it is preferable that the second electric potential V2 of the second driving signal COM 2 corresponds to a coercive electric field of the second piezoelectric element 302.

Further, the compression element P31, the holding element P32 and the expansion element P33 of the second driving signal COM 2 are configured so as to appear during the second holding element P24 of the first driving signal COM 1. That is, a configuration is made such that, only when one of the two kinds of driving signals applies a coercive electric field (the second electric potential V2) to one of the two kinds of the piezoelectric elements 300 provided for each of the nozzle openings 21, the other one of the two kinds of driving signals applies a maximum electric field (the first electric potential V1) to the other one of the two kinds of the piezoelectric elements 300 provided for each of the nozzle openings 21. Applying an electric field to each of the piezoelectric elements 300 provided for each of the nozzle openings 21 in this way makes it possible to take full advantage of a distortion of the each piezoelectric element 300 in ejection of a droplet, and further, suppress the influence of increase of a residual distortion of the each piezoelectric element 300. In addition, in the above example, the compression element P31, the holding element P32 and the expansion element P33 of the second driving signal COM 2 are configured so as to appear during the second holding element P24 of the first driving signal COM 1, but the configuration is not particularly limited to this. For example, even if timing at which the expansion element P33 of the second driving signal COM 2 descends to the second electric potential V2 is configured so as to be the same as timing at which the second expansion element P25 of the first driving signal COM 1 ascends to the intermediate electric potential VM, this configuration does not cause any particular problem.

Further, when the first driving signal COM 1 and the second driving signal COM 2 such as described above are applied to the first piezoelectric element 301 and the second piezoelectric element 302, respectively, the first piezoelectric element 301 is deformed by the first expansion element P21 of the first driving signal COM 1 in a direction in which the volume of the pressure generation chamber 12 is expanded, and thereby a meniscus inside the nozzle opening 21 is pulled in in a direction towards the pressure generation chamber 12. Subsequently, the first piezoelectric element 301 is deformed by the first compression element P23 in a direction in which the volume of the pressure generation chamber 12 is compressed. Subsequently, the second piezoelectric element 302 is deformed by the compression element P31 of the second driving signal COM 2 in a direction in which the volume of the pressure generation chamber 12 is compressed. That is, the volume of the pressure generation chamber 12, which has been compressed by the first compression element P23 of the first driving signal COM 1, is further compressed by the compression element P31 of the second driving signal COM 2. In this way, ink inside the pressure generation chamber 12 is pressurized and a meniscus inside the pressure generation chamber 12 is largely pushed out from the pressure generation chamber 12 side, so that the ink is ejected as an ink droplet through the nozzle opening 21. Subsequently, the pressure generation chamber 12 is restored by the expansion element P33 of the driving signal COM 2 to a state where the volume of the pressure generation chamber 12 has been compressed by the first compression element P23 of the driving signal COM 1, and then, the pressure generation chamber 12 is restored by the second expansion element P25 of the driving signal COM 1 to a baseline volume thereof corresponding to the intermediate electric potential VM.

Further, the same waveform as that of the driving signal COM 2, shown in FIG. 7B, may be applied to the first piezoelectric element 301. Driving signals in this case are illustrated in FIGS. 8A and 8B.

The first driving signal COM 1 is a signal to be applied to the second electrode 80 which is a discrete electrode of each of the first piezoelectric elements 301, and as shown in FIG. 8A, the first driving signal COM 1 includes an ejection pulse generated for each recording cycle T. This ejection pulse included in the first driving signal COM 1 is composed of a first expansion element P41 which expands the pressure generation chamber 12 by ascending from a state where the second electric potential V2 is maintained to the first electric potential V1; a holding element P42 which maintains the first electric potential V1; and a compression element P43 which compresses the pressure generation chamber 12 by descending from the first electric potential V1 to the second electric potential V2. In addition, it is preferable that the second electric potential V2 of the first driving signal COM 1 corresponds to a coercive electric field of the first piezoelectric element 301.

Meanwhile, the second driving signal COM 2 is a signal to be applied to the second electrode 80 which is a discrete electrode of each of the second piezoelectric elements 302, and as shown in FIG. 8B, the second driving signal COM 2 includes an ejection pulse generated for each recording cycle T. This ejection pulse included in the second driving signal COM 2 is composed of an expansion element P51 which expands the pressure generation chamber 12 by descending from a state where the intermediate electric potential VM is maintained to the second electric potential V2; a holding element P52 which holds the second electric potential V2 for a predetermined period of time; a first compression element P53 which compresses the pressure generation chamber 12 by ascending from the second electric potential V2 to the first electric potential V1; a second holding element P54 which holds the first electric potential V1 for a predetermined period of time; and a second expansion element P55 which expands the pressure generation chamber 12 by descending from the first electric potential V1 to the intermediate electric potential VM. In addition, it is preferable that the second electric potential V2 of the second driving signal COM 2 corresponds to a coercive electric field of the second piezoelectric element 302.

Further, the expansion element P41, the holding element P42 and the compression element P43 of the first driving signal COM 1 are configured so as to appear during the first holding element P52 of the second driving signal COM 2. That is, a configuration is made such that, only when one of the two kinds of driving signals applies a coercive electric field (the second electric potential V2) to one of the two kinds of the piezoelectric elements 300 provided for each of the nozzle openings 21, the other one of the two kinds of driving signals applies a maximum electric field (the first electric potential V1) to the other one of the two kinds of the piezoelectric elements 300 provided for each of the nozzle openings 21. Applying an electric field to each of the piezoelectric elements 300 provided for each of the nozzle openings 21 in this way makes it possible to take full advantage of a distortion of the each piezoelectric element 300 in ejection of a droplet, and further, suppress the influence of increase of a residual distortion of the each piezoelectric element 300.

In addition, in the above driving signals shown in FIGS. 7A and 7B, the second electric potential V2 of the second driving signal COM 2 is made a coercive electric field of the second piezoelectric element 302, and in the above driving signals shown in FIGS. 8A and 8B, the second electric potential V2 of the first driving signal COM 1 is made a coercive electric field of the first piezoelectric element 301, but the configuration is not particularly limited to this, and the electric potential value of the second electric potential V2 may be made 0 V, or the application of the second electric potential V2 may be made OFF. In this case, a circuit for generating a negative electric potential becomes unnecessary, and cost therefor can be reduced.

### Other Embodiments

Hereinbefore, an embodiment according the invention has been described, but a fundamental configuration of the invention is not limited to the aforementioned configuration.

For example, in embodiment 1 described above, the first piezoelectric element 301 and the second piezoelectric element 302 are configured so as to be arranged in parallel to each other in the first direction X, but the configuration is not limited to this. Here, another example of the actuator apparatus is illustrated in FIGS. 9A and 9B. In addition, FIG. 9A is a plan view of a flow path formation substrate in a modified example of the ink jet recording head, and FIG. 9B is a cross-sectional view taken along the line IXB-IXB of FIG. 9A.

As shown FIGS. 9A and 9B, first piezoelectric elements 301 are formed at positions each facing a corresponding one of both edge portions of each of the pressure generation chambers 12 in a second direction Y. Further, a second piezoelectric element 302 is formed between the two first piezoelectric elements 301. Even in such a configuration, just like embodiment 1 described above, the first piezoelectric element 301 and the second piezoelectric element 302 are located so as to compensate for each other's residual distortion, and thus, it is possible to suppress the influence of increase of a residual distortion of each of the piezoelectric elements 300 and thereby suppress the influence of a reduction of a displacement amount of each of the piezoelectric elements 300 over a long period of time.

Further, as shown in FIG. 10, the configuration may be made such that, for each of the pressure generation chambers 12, the piezoelectric elements 301 which are according to embodiment 1 described above and which are arranged in parallel to each other in the first X direction and the piezoelectric elements 301 which are shown in FIGS. 9A and 9B and which are arranged in parallel to each other in the second Y direction are combined. In addition, FIG. 10 is a plan view of a flow path formation substrate in a modified example of the ink jet recording head.

That is, as shown in FIG. 10, the first piezoelectric elements 301 are formed in areas each facing a corresponding one of both edge portions of each of the pressure generation chambers 12 in the first direction X. Further, the first piezoelectric elements 301 are formed in areas each facing a corresponding one of both edge portions of each of the pressure generation chambers 12 in the second direction Y. That is, the first piezoelectric elements 301 whose total number is four are formed for each of the pressure generation chambers 12. Further, one of the second piezoelectric elements 302 is formed so as to be surrounded by the four first piezoelectric elements 301.

According to such a configuration, a driving area of the piezoelectric elements 300 provided for each of the pressure generation chambers 12 is made larger, so that it becomes possible to enhance the characteristic of ink ejection.

In addition, the same driving signal (COM 1) is simultaneously applied to the plurality of first piezoelectric elements 301 which is provided for each of the pressure generation chambers 12, and thus, the second electrode 80, which is a discrete electrode, may be continuously provided across each of the plurality of first piezoelectric elements 301.

Further, the piezoelectric substance layer 70 may be continuously provided across not only each of the first piezoelectric elements 301 themselves but also each of the second piezoelectric element 302 and the first piezoelectric elements 301, provided that the scope of each of the active portions 320 is defined by the second electrode 80 which is a discrete electrode.

Moreover, in embodiment 1 described above, an ink droplet is ejected by driving the two first piezoelectric elements 301 and the second piezoelectric element 302, but the configuration is not particularly limited to this, and, for example, an ink droplet may be ejected by using only any one of the two kinds of the piezoelectric elements 300, that is, by using only one of either the two first electric elements 301 or the second electric element 302. In this case, the other one of the two kinds of the piezoelectric elements 300 may be driven through, for example, so-called slight vibration driving, in which the other one of the two kinds of the piezoelectric elements 300 is deformed to a degree that does not eject any ink droplet at timing not associated with any ejection of an ink droplet, or so-called flushing, in which cleaning is performed by ejecting ink droplets onto a non-printing area, that is, an area not facing the recording sheet S. When the other one of either the two first piezoelectric elements 301 or the second piezoelectric element 302 is configured so as not to be associated with the ejection of ink droplets in such a way as described above, the characteristic of ejection of ink droplets degrades, but the first piezoelectric element 301 and the second piezoelectric element 302 compensate for each other's increase of a residual distortion, so that it becomes possible to suppress the influence of a reduction of a displacement amount, due to repeated driving operations.

Moreover, in embodiment 1 described above, for example, the elastic film 51 made of oxide silicon and the insulator film 52 made of zirconium oxide are provided, but the configuration is not particularly limited to this. For example, as the elastic film 51, a material, such as a silicon nitride film, a polysilicon film or an organic film (polyimide, parylene or the like), may be employed. Further, as the insulator film 52, a material, such as titanium oxide (TiO₂), aluminum oxide (Al₂O₃) , hafnium oxide (HfO₂), magnesium oxide (MgO) or lanthanum aluminate (LaAlO₃), may be employed.

Further, in embodiment 1 described above, the piezoelectric element 300 of thin film type has been described as a pressure generation means for ejecting ink droplets through the nozzle opening 21, but the configuration is not limited to this. For example, a thick-film type piezoelectric actuator, which is formed in a method of bonding a green sheet or the like, or a laminated piezoelectric actuator obtained by alternately laminating a piezoelectric material and an electrode formation material, may be employed.

In the aforementioned ink jet recording apparatus II, a configuration in which the ink jet recording head I (the head unit 1) mounted on the carriage 3 is moved in the main-scanning direction has been exemplified, but the configuration is not particularly limited to this. For example, the invention can be applied to a so-called line-type recording apparatus which performs printing merely by moving the recording sheet S in a sub-scanning direction, such as paper, under the state where the ink jet recording heads I are fixed.

Further, in the aforementioned example, the ink jet recording apparatus II is configured such that the cartridges 2, each being a liquid storage means, are mounted on the carriage 3, but the configuration is not particularly limited to this. For example, the configuration may be made such that a liquid storage means, such as an ink tank, is fixed to the apparatus body 4, and the liquid storage means is connected to each of the ink jet recording heads I via a feed pipe, such as a tube. Further, the liquid storage means may not be mounted in the ink jet recording apparatus II.

In addition, in the aforementioned embodiments, the ink jet recording head and the ink jet recording apparatus have been described as an example of a liquid ejecting head and an example of a liquid ejecting apparatus, respectively, but the invention is intended to widely target the whole of liquid ejecting heads and liquid ejecting apparatuses, and naturally, the invention can be applied to liquid ejecting heads and liquid ejecting apparatuses each ejecting liquid other than ink. The liquid ejecting heads each ejecting liquid other than ink includes, for example, various recording heads for use in image recording apparatuses, such as printers, color material ejecting heads for use in manufacturing of color filters for liquid crystal displays and the like, electrode material ejecting heads for use in formation of electrodes for organic electroluminescence displays, field emission displays (FED) and the like, living organic material ejecting heads for use in manufacturing of biochips, and the like, and further, the invention can be applied to liquid ejection apparatuses each provided with such a liquid ejecting head as described above.

Further, the scope of the invention is not limited to an actuator apparatus which is mounted in a liquid ejecting head typified by the ink jet recording head, and the invention can be also applied to an actuator apparatus which is mounted in an apparatus other than the liquid ejecting head, such as an ultrasonic device included in an ultrasonic transmitter and the like, an ultrasonic motor, a pressure sensor or a pyroelectric sensor.

What is claimed is:

1. A liquid ejecting head comprising:
a flow path formation substrate provided with a pressure generation chamber communicated with at least one nozzle opening through which liquid is ejected; and
an actuator apparatus including a vibration plate provided at one face side of the flow path formation substrate and a plurality of piezoelectric elements being formed on the vibration plate, wherein
the actuator apparatus includes two first piezoelectric elements arranged at positions facing edge portions in at least one direction of the pressure generation chamber and a second piezoelectric element arranged between the two first piezoelectric elements.

2. The liquid ejecting head according to claim 1, wherein the at least one direction corresponds to a direction in which the nozzle openings are aligned.

3. The liquid ejecting head according to claim 1, wherein the first piezoelectric elements are arranged at areas facing edge portions in a direction orthogonal to the at least one direction of the pressure generation chamber.

4. A liquid ejecting apparatus comprising the liquid ejecting head according to claim 1.

5. A liquid ejecting apparatus comprising the liquid ejecting head according to claim 2.

6. A liquid ejecting apparatus comprising the liquid ejecting head according to claim 3.

7. The liquid ejecting apparatus according to claim 4, further comprising a control apparatus that supplies the first piezoelectric elements with a first driving signal and the second piezoelectric element with a second driving signal different from the first driving signal.

8. The liquid ejecting apparatus according to claim 5, further comprising a control apparatus that supplies the first piezoelectric elements with a first driving signal and the second piezoelectric element with a second driving signal different from the first driving signal.

9. The liquid ejecting apparatus according to claim 6, further comprising a control apparatus that supplies the first piezoelectric elements with a first driving signal and the second piezoelectric element with a second driving signal different from the first driving signal.

10. An actuator apparatus comprising:
a vibration plate that defines and forms a face of a space portion; and
a plurality of piezoelectric elements being formed on the vibration plate and including two first piezoelectric elements arranged at positions facing edge portions in at least one direction of the space portion and a second piezoelectric element arranged between the two first piezoelectric elements.
